(19) United States
(12) Patent Application Publication
(10) Pub. No.: US 2026/0303026 A1
(43) Pub. Date: Oct. 1, 2026

(54) WIDEBAND DOHERTY POWER AMPLIFIER

(71) Applicants: Wipro Limited, Bangalore (IN); Indian Institute of Technology Roorkee, Roorkee (IN)

(72) Inventors: Dushyant Kumar SHARMA, Bengaluru (IN); Karun RAWAT, Roorkee (IN); Mohammad Abdul SHUKOOR, Roorkee (IN); Ahmad Zakaria AHMAD, Roorkee (IN)

(73) Assignees: Wipro Limited, Bangalore (IN); Indian Institute of Technology Roorkee, Roorkee (IN)

(21) Appl. No.: 19/211,834

(22) Filed: May 19, 2025

(30) Foreign Application Priority Data
Mar. 29, 2025 (IN) 202541030846

(51) Int. Cl. H03F 1/02; H03F 3/21

(52) U.S. Cl. CPC H03F 1/0288; H03F 3/211; H03F 2200/171

(57) ABSTRACT

A Doherty power amplifier is disclosed. The Doherty power amplifier may include a first set of m-derived filters coupled to an output of a main transistor of a main path of the Doherty power amplifier. The Doherty power amplifier may also include a second set of m-derived filters coupled to an output of an auxiliary transistor of an auxiliary path of the Doherty power amplifier. The Doherty power amplifier may also include a third set of m-derived filters coupled to a junction point of the main path and the auxiliary path. Further, the Doherty power amplifier may be configured to operate at a predefined back-off power range in a predefined frequency range.

### TECHNICAL FIELD

This disclosure generally relates to the field of power amplifiers. More particularly, the disclosure relates to a wideband Doherty power amplifier.

### BACKGROUND

In wireless communication systems, advanced modulation techniques, such as Quadrature Amplitude Modulation (QAM) and Orthogonal Frequency Division Multiplexing (OFDM) are utilized to meet the requirement of high data rates while exploiting spectrum efficiently. However, this results in a large envelope variation in the wireless communication signals with high peak-to-average power ratio (PAPR) characteristics. Consequently, the operation of Power Amplifiers (PAs) in the transmitter's front-end must have headroom to accommodate these high PAPR signals to avoid distortion caused by signal clipping. In such a case, it is essential to operate PA at output power back-off (OPBO) from its saturation. However, the conventional PA designs operate at high efficiency near their saturation and operating them at significant output power back-off (OPBO) leads to reduced efficiency, increased operational expenses (OPEX), and degraded wireless link performance.

To address these challenges, several efficiency-boosting PA topologies have been proposed, where the device is operated at voltage saturation over a varying input drive. Doherty Power Amplifier (DPA) is one of a popular choice in wireless base stations due to its simplicity and fully analogue architecture, which efficiently handles high PAPR signals across a wide dynamic range.

However, utilization of conventional matching techniques in DPA poses a significant challenge for operating DPA over a wide bandwidth and a wide dynamic range of input power drive variation inherent in DPA operation.

Therefore, there is a requirement for an efficient Doherty Power Amplifier that may operate over a wide bandwidth and a wide dynamic range of input power drive variation.

### SUMMARY OF THE INVENTION

In one embodiment, a Doherty power amplifier is disclosed. The Doherty power amplifier may include a first set of m-derived filters coupled to an output of a main transistor of a main path of the Doherty power amplifier. The Doherty power amplifier may also include a second set of m-derived filters coupled to an output of an auxiliary transistor of an auxiliary path of the Doherty power amplifier. Further, the Doherty power amplifier may include a third set of m-derived filters coupled to a junction point of the main path and the auxiliary path. It may be noted that the Doherty power amplifier may operate at a predefined back-off power range in a predefined frequency range.

In another embodiment, a wideband Doherty power amplifier is disclosed. The wideband Doherty power amplifier may include a first set of m-derived filters coupled to an output of a main transistor of a main path of the wideband Doherty power amplifier. The wideband Doherty power amplifier may also include a second set of m-derived filters coupled to an output of an auxiliary transistor of an auxiliary path of the wideband Doherty power amplifier. Further, the wideband Doherty power amplifier may include a third set of m-derived filters coupled to a junction point of the main path and the auxiliary path. It may be noted that the wideband Doherty power amplifier may operate at a predefined back-off power range in a predefined frequency range.

It is to be understood that both the foregoing general description and the following detailed description are exemplary and explanatory only and are not restrictive of the invention, as claimed.

### BRIEF DESCRIPTION

The accompanying drawings, which are incorporated in and constitute a part of this disclosure, illustrate exemplary embodiments and, together with the description, serve to explain the disclosed principles.

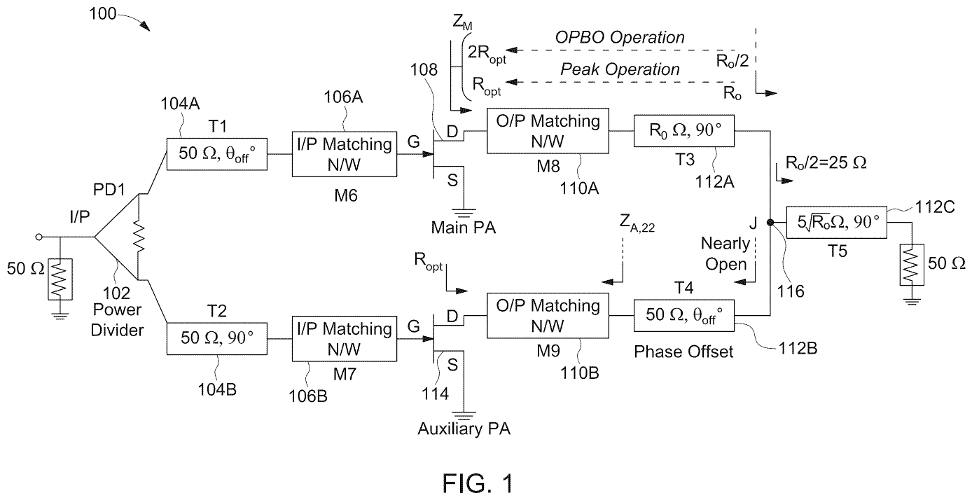

FIG. 1 illustrates a circuit diagram of a conventional Doherty power amplifier.

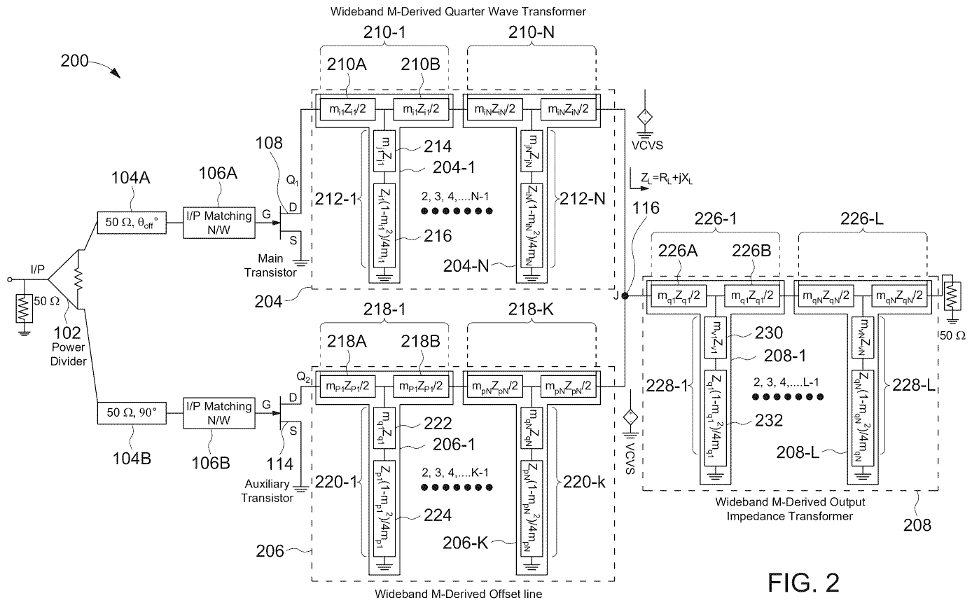

FIG. 2 illustrates a wideband Doherty power amplifier incorporating m-derived filters, in accordance with an embodiment of the present disclosure.

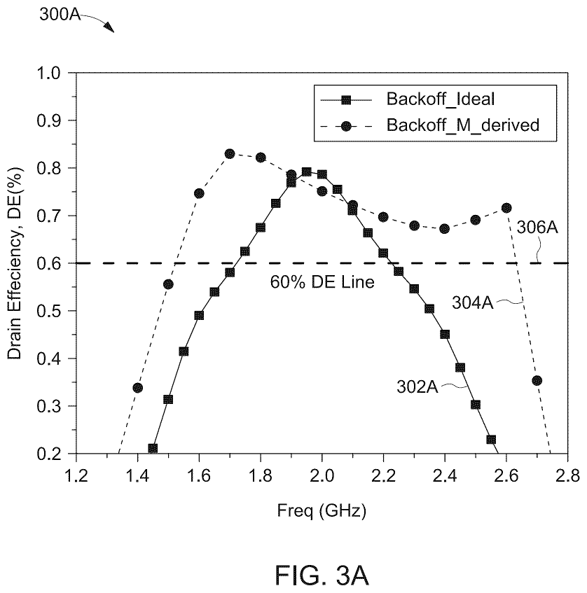

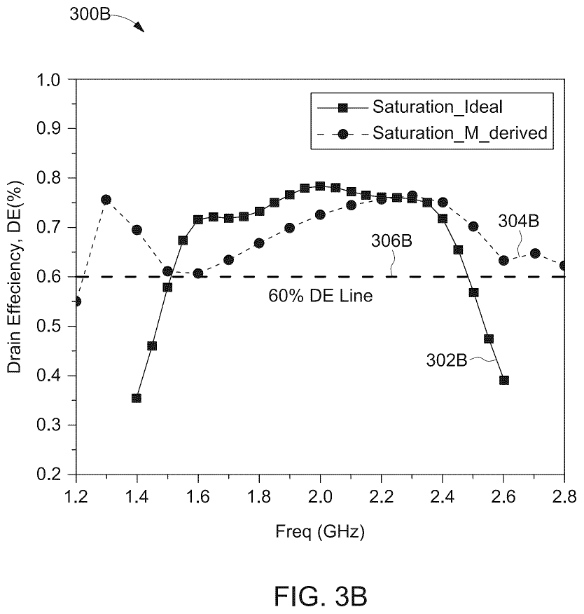

FIG. 3A illustrates simulated results depicting the drain efficiency of the Doherty power amplifier of FIG. 2 as compared to the conventional Doherty power amplifier at a back-off power point, in accordance with an embodiment of the present disclosure.

FIG. 3B illustrates simulated results depicting the drain efficiency of the Doherty power amplifier of FIG. 2 as compared to the conventional Doherty power amplifier at saturation point, in accordance with an embodiment of the present disclosure.

### DETAILED DESCRIPTION OF THE DRAWINGS

The foregoing description has broadly outlined the features and technical advantages of the present disclosure in order that the detailed description of the disclosure that follows may be better understood. Additional features and advantages of the disclosure will be described hereinafter which forms the subject of the claims of the disclosure. It should be appreciated by those skilled in the art that the conception and specific embodiments disclosed may be readily utilized as a basis for modifying other devices, systems, assemblies, and mechanisms for carrying out the same purposes of the present disclosure. It should also be realized by those skilled in the art that, such equivalent constructions do not depart from the scope of the disclosure as set forth in the appended claims. The novel features which are believed to be characteristics of the disclosure, to its device or system, together with further objects and advantages will be better understood from the following description when considered in connection with the accompanying figures. It is to be expressly understood, however, that each of the figures is provided for the purpose of illustration and description only and is not intended as a definition of the limits of the present disclosure.

The terms “including”, “comprises”, “comprising”, “comprising of” or any other variations thereof, are intended to cover a non-exclusive inclusion, such that a system or a device that comprises a list of components or steps does not include only those components or steps but may include other components or steps not expressly listed or inherent to such setup or device. In other words, one or more elements in a system or apparatus proceeded by “comprises . . . a” does not, without more constraints, preclude the existence of other elements or additional elements in the system or apparatus.

Exemplary embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the scope of the disclosed embodiments. It is intended that the following detailed description be considered exemplary only, with the true scope being indicated by the following claims. Additional illustrative embodiments are listed.

Further, the phrases “in some embodiments”, “in accordance with some embodiments”, “in the embodiments shown”, “in other embodiments”, and the like mean a particular feature, structure, or characteristic following the phrase is included in at least one embodiment of the present disclosure and may be included in more than one embodiment. In addition, such phrases do not necessarily refer to the same embodiments or different embodiments. It is intended that the following detailed description be considered exemplary only, with the true scope being indicated by the following claims.

Reference will now be made to the exemplary embodiments of the disclosure, as illustrated in the accompanying drawings. Wherever possible, same numerals have been used to refer to the same or like parts. The following paragraphs describe the present disclosure with reference to FIGS. 1-3B.

Referring now to FIG. 1, a circuit diagram of a conventional Doherty power amplifier (DPA) 100 is illustrated. The conventional DPA 100 may include an input power divider 102 that may divide an input power between a main path and an auxiliary path. The main path may include a first input offset line 104A, a first input matching network 106A, a main transistor 108, a first output matching network 110A and a first quarter wave transformer (QWT) 112A. It may be noted that the first input offset line 104A and the first input matching network 106A are connected to an input of the main transistor 108 and the first output matching network 110A and the first QWT 112A are connected at an output of the main transistor 108.

Further, the auxiliary path may include a second input offset line 104B, a second input matching network 106B, an auxiliary transistor 114, a second output matching network 110B and a second QWT 112B (also referred to as a phase-offset component). It may be noted that the second input offset line 104B and the second input matching network 106B are connected to an input of the auxiliary transistor 114 and the second output matching network 110B and the second QWT 112B are connected at an output of the auxiliary transistor 114. Further, the main path and the auxiliary path may converge at a junction point (J) 116. Further, a third QWT 112C is connected to the junction point 116. In an exemplary embodiment, the conventional Doherty power amplifier 100 as illustrated in FIG. 1, may transform 50Ω standard load to a required impedance at junction point 116. Further, it may be noted that the main path may operate as a main power amplifier (PA) and the auxiliary path may operate as an auxiliary PA.

In one embodiment, the conventional Doherty power amplifier may function as a linear amplifier in case, a lower-power signal is received as an input signal. For the lower-power signal, the conventional Doherty power amplifier operates in a class-AB or class-B mode. In other words, for the lower-power signal, only the main PA operates and the load combiner will provide appropriate impedance matching to the main PA for efficiently amplifing the input signal. However, the auxiliary PA remains inactive.

At low power levels, the main PA may operate independently while the auxiliary PA may remain inactive. This may be possible as the main PA will be biased (gate voltage value setting) at its pinch-off or slightly above the pinch-off. This will ensure the main PA to operate at low power levels, whereas, the auxiliary PA will be biased well below the pinch-off, which will enable the auxiliary PA to operate only when the input power drive is high and crosses a certain threshold value.

In another embodiment, in case the conventional Doherty power amplifier receives a higher-power input signal, then both the main PA and the auxiliary PA will operate. The input signal may be determined as a lower-power input signal or a higher-power operating signal based on a comparison with a predefined threshold OPBO.

FIG. 1 illustrates the first output-matching network 110A and the second output-matching network 110B may match the main transistor 108 and the auxiliary transistor 114 of the main PA and the auxiliary PA, respectively, to their optimal loads. In conventional DPA 100, load modulation may present a varying load impedance at an output of the first matching network 110A in accordance with an interaction of currents of the main PA and the auxiliary PA. The first QWT 112A in the main path may further be used to provide impedance inversion from an inherent low impedance seen by the main path towards junction 116 to a required high impedance value that may be seen by the main PA matching network at back-off power range. It may be noted that the inherent low impedance seen by the main path towards junction 116 may be equal to R₀/2. Further, the required high impedance value that may be seen by the main PA matching network at back-off may be equal to 2R₀. In order to meet this requirement of the main PA to operate in saturation region at back-off power level that may result in desired high efficiency at low power region. An additional phase of 90° is added at the output of the main PA by adding the first QWT 112A, and a phase offset of 90° is added at the input of the auxiliary PA by adding the second QWT 104B.

FIG. 1 also shows that the phase offset line is enabled by the second QWT 112B in the auxiliary path to ensure that no current leaks from the main path to the auxiliary PA when the auxiliary PA is OFF. The current may leak due to the transistor parasitics used for the auxiliary PA, the second input matching network 106B and the second output matching network 110B, which may present a non-open circuit impedance Z_{A,22} as shown in FIG. 1. Examples of the components may include, but not limited to, a resistor, an inductor, a capacitor or the combination of one or more of the mentioned components. Thus, the phase offset line enabled by the second QWT 112B may transform the non-open circuit impedance Z_{A,22} to an open circuit at junction point 116. This may ensure that the main PA current does not leak to the auxiliary PA. In order to compensate for this, an extra phase offset θ_{eff} may be added at the output of the auxiliary path using the second QWT 112B, and the first input offset line 104A is used in the main path that may provide the same phase offset of θ_{eff}. It may be noted that since the load terminating at junction point 116 is R₀/2 (where R₀ is typically 50Ω), a third QWT 112C is used to transform the standard R₀ load to the required load at junction point 116. By way of an example, the first matching network 110A and the second matching network 110B are connected between a drain and a load of the main transistor 108 and the auxiliary transistor 114, respectively, such that it transforms an optimised amount of input power to the load while presenting the input impedance equal to the complex conjugate of the drains' output impedance.

The aforementioned configuration is achieved by biasing the main PA at the pinch-off voltage or above the pinch-off voltage (in class-AB mode), and the auxiliary PA is biased to operate below the pinch-off voltage or in class-C mode. Thus, a DPA architecture is required that can present a design scheme for impedance inversion, matching of the main PA and the auxiliary PA and parasitic cancellation at the auxiliary path together in a single unit for optimal operation. The main amplifier be presented with a load impedance higher than the optimal value of the load impedance, which leads the main amplifier to operate in saturation region at the, back-off power range to deliver efficient output for the lower-power input signals. This will enable a wideband operation and a wide dynamic range in the DPA operation. Therefore, there is a requirement for a DPA that accommodates frequency-dependent variations in transformer ratios and phase offsets caused by device parasitics, ensuring optimal impedance transformation and desired phase shifts over the bandwidth.

Referring now to FIG. 2, a wideband Doherty power amplifier (DPA) 200 incorporating m-derived filters is illustrated in accordance with some embodiments of the present disclosure. The conventional Doherty power amplifier 100 fails to operate in wider bandwidth due to a specific electrical length requirement of a transmission line corresponding to a frequency of the input signal. The electrical length of the transmission line is inversely proportional to the frequency of the input signal. The conventional Doherty power amplifier 100 fails to realise the electrical length requirement of the input signal with a frequency range below a predefined threshold frequency value. Therefore, the aforementioned requirement for the electrical length limits the operational frequency range of the conventional Doherty power amplifier 100. The Doherty power amplifier 200 of FIG. 2 is designed for high-efficiency, wideband operation that utilizes m-derived low-pass sections for output matching, impedance transformation, and phase compensation, ensuring optimal performance across a broad predefined frequency range.

The Doherty power amplifier 200 may include two main branches. The main amplifier path comprises a first input matching network 106A, the main transistor 108 and a first set of m-derived filters 204-1-204-N (collectively referred to as “first set of m-derived filters 204” and individually referred to as “first m-derived filter 204”). The first set of m-derived filters 204 (also referred to as “m-derived QWT”) is coupled to the output of the main transistor 108 of the main path and may act as a wideband m-derived QWT for impedance matching and impedance transformation. Further, the auxiliary amplifier path of the Doherty power amplifier 200 may include a second input matching network 106B, the auxiliary transistor 114 and a second set of m-derived filters 206-1-206-K (collectively referred to as a second set of m-derived filters 206 and individually referred to as second m-derived filter 206). The second set of m-derived filters 206 are coupled to the output of the auxiliary transistor 114 of the auxiliary path. The auxiliary amplifier path may mirror the main path with its input-matching network. The second set of m-derived filters 206 implement a wideband m-derived offset line instead of the m-derived QWT. Further, the Doherty power amplifier 200 may include a third set of m-derived filters 208-1-208-L (referred to as a third set of m-derived filters 208 and individually referred to as a third m-derived filter 208).

It may be noted that the first set of m-derived filters 204 may include a first count of first m-derived filters 204 represented by ‘N’. The second set of m-derived filters 206 may include a second count of second m-derived filters represented by ‘K’. The third set of m-derived filters 208 may include a third count of third m-derived filters represented by ‘L’.

It may be noted that the Doherty power amplifier 200 may operate at a predefined back-off power range in a predefined frequency range. Thus, both paths are combined using a wideband m-derived output impedance transformer, ensuring efficient power combining and impedance matching at the output over a wideband. Further, ‘N’, ‘K’ and ‘L’ are natural numbers that may be determined based on an operating frequency in the predefined frequency range. It may be noted that the first set of m-derived filters 204 may implement a wideband quarter wave (QWT), the second set of m-derived filters 206 may implement a phase offset line, and the third set of m-derived filters 208 may implement a wideband output impedance transformer.

Further, the first input offset line 104A i.e. 5002 input transmission line with electrical length θ_{eff} in the main path and the second input offset line 104B in the auxiliary path i.e. 50Ω QWT may also be implemented using a set of m-derived filters for the wideband phase compensation required for the operation of the DPA 200.

The main path of the Doherty power amplifier 200 may incorporate the first set of m-derived filters 204 for wideband impedance inversion and impedance transformation. Additionally, the first set of m-derived filters 204 may transform the main transistor 108 from behaving as a current source into a constant voltage source at the junction point 116 over the predefined frequency range. In other words, the first set of m-derived filters 204 may combine the functioning of the first output matching network 110A and the first QWT 112A of the conventional DPA 100. The set of parasitic components of the main transistor 108 may be absorbed in the first set of m-derived filters 204 and the impedance inversion may also be performed for obtaining required loads to the main transistor 108 from an effective impedance obtained at the junction point 116 in accordance with the proposed design of the DPA 200.

It should be noted that the transmission line may be represented as an m-derived low-pass filter section, thus the value of ‘m’ factor may be obtained using the equation (1) below:

$$m = \sqrt{1 - {( \frac{{f}_{c}}{{f}_{∞}} )}^{2}} \qquad ( 1 )$$

Wherein, f_{c} denotes the cut-off frequency and f_{∞} denotes the frequency when the denominator of a transfer function may become zero, especially at a stop band frequency. It may be noted that the value of the m-factor ranges from 0 to 1 and in a preferred embodiment, the value of the m-factor may be about 0.6 for impedance matching.

The first set of m-derived filters 204 and the second set of m-derived filters 206 may be coupled between a drain of the main transistor 108 and the auxiliary transistor 114, respectively.

The proposed architecture of FIG. 2 offers significant improvements over traditional Doherty PA designs. Incorporation of the m-derived filters 204, 206, 208 enable wideband performance through integration of frequency-agile m-derived quarter-wave transformer (QWT) 204, m-derived offset line 206, and m-derived output impedance transformer 208. The m-derived filters mimic transmission lines with non-linear variations in phase and image impedance, allowing for tailored performance across a wide frequency band. Consequently, the proposed DPA architecture 200 addresses key imperfections, such as preventing main current leakage into the auxiliary path when the auxiliary PA is OFF and ensuring the provision of optimal load impedance. The DPA 200 accommodates frequency-dependent variations in transformer ratios and phase offsets caused by device parasitics, ensuring optimal impedance transformation and desired phase shifts over the predefined bandwidth. By combining the first input matching network 110A and the first QWT 112A that acts as an impedance inverter into a single wideband m-derived QWT 204 the architecture 200 directly matches the load modulation requirements at the transistor's intrinsic reference plane, ensuring consistent performance across a broad input voltage drive range. Additionally, the second set of m-derived filters 206 that enables the offset line and the third set of m-derived filter 208 that enables the output impedance transformer are seamlessly integrated with the first m-derived filters 204 to ensure high efficiency at back-off power levels. In addition, in lower frequency bands below 1 GHz, the proposed DPA architecture 200 can be significantly miniaturized as the required phase delay for Doherty operation is achieved using lumped components.

Further, each of the first set of m-derived filters 204, the second set of m-derived filters 206 and the third set of m-derived filters 208 may be topologically arranged in one of a lumped configuration, a quasi-lumped configuration and/or a fully transmission line configuration.

As mentioned earlier, each of the first set of m-derived filters 204 may be symmetrical and include the ‘N’ count of the first set of m-derived filters 204 may be determined based on the predefined frequency of operation, optimum loads for different devices and corresponding parasitic values. Each first m-derived filter 204 may be symmetrical and includes a series arm inductor 210(1-N) and a shunt arm resonator 212(1-N) that helps in achieving wideband performance. Further, since the ‘N’ may vary for each first m-derived filter 204, the component values may also differ in each first m-derived filter 204. The impedance value of the series arm inductor 210(1-N) may be denoted as mᵢ₁Zᵢ₁, mᵢ₂Zᵢ₂, . . . , m_{iN}Z_{iN} corresponding to each of the first set of m-derived filters 204-1, 204-2, . . . , 204-N respectively. The impedance value of the series arm inductor 210(1-N) may be distributed on either side of the series resonator 212(1-N) connected in the shunt arm of the first m-derived filter 204, as 210A(1-N) and 210B(1-N) to maintain the symmetry.

Upon varying the value of the m-factor, impedance value may span from an open value to a short value. The open value may refer to a very large value or an ideally infinite value, and the short value may refer to a very small value or an ideally zero value. Further, impedance value of a corresponding capacitor 214(1-N) of the corresponding shunt arm series resonator 212(1-N) may be in the form of mⱼ₁Zⱼ₁, mⱼ₂Zⱼ₂, . . . , m_{iN}Z_{iN}. Further, impedance value of a corresponding inductor 216(1-N) of the corresponding shunt arm series resonator 212(1-N) may be in the form of

$${Z}_{i 1} ( 1 - {m}_{i 1}^{2} ) / 4 {m}_{i 1} , … {Z}_{iN} ( 1 - {m}_{i N}^{2} ) / 4 {m}_{i N} ,$$

corresponding to each of the first set of m-derived filters 204. The capacitance (Cᵢ₁, . . . , C_{iN}) of a corresponding capacitor 214(1-N) and inductance (Lᵢ₁, . . . , L_{iN}) of the corresponding inductor 216(1-N) for the corresponding characteristic impedance (Zᵢ₁, . . . , Z_{iN}) may be determined as per equations (2) and (3) respectively given below:

$${L}_{i N} = \frac{{Z}_{i N}}{2 π {f}_{c}} \qquad ( 2 )$$

$${C}_{j N} = \frac{1}{2 π {Z}_{j N} {f}_{c}} \qquad ( 3 )$$

It may be noted that the values of the series and shunt arms of each first m-derived filter 204 are carefully chosen such that it would show the higher-order non-linear transmission phase, which has slower phase transition with reference to frequency and is responsible for achieving efficient wideband DPA operation. The phrase or electrical length may be adjusted by considering the higher-order first m-derived filters 204 by optimizing the L and C for the respective electrical length by adjusting the cut-off frequency. Given the frequency-dependent nature of the device parasitics, the impedance transformation ratio required by the QWT may vary in practical scenarios. The first set of m-derived filters 204 with their ability to achieve variable image impedance, enable the necessary transformation across the frequency band, thereby equipping the m-derived QWT 204 with wideband capability. The matching network and impedance inverter are integrated into a single unit, the wideband m-derived QWT 204. Consequently, load modulation at the junction point 116 across a wide frequency band appropriately transforms to the required load modulation at the transistor's intrinsic current generator reference plane. This ensures optimal performance across a wide range of input drive levels and over a broad bandwidth. In the lower frequency band (e.g. below 1 GHZ), the design implementation of the DPA 200 may be effectively miniaturized since the necessary phase delay required for the operation of the DPA 200 is obtained from components arranged in a lumped configuration.

Further, the second set of m-derived filters 206 may be coupled to an output of an auxiliary transistor 114 of an auxiliary path of the Doherty power amplifier 200. The second set of m-derived filters 206 may be coupled between the drain of the auxiliary transistor 114 and the junction point 116. The second set of m-derived filters 206 may include a second count of m-derived filters ‘K’, denoted as 206(1-K). The second count ‘K’ of the second set of m-derived filters 206 may be determined based on the operating frequency in the predefined frequency range. Each second m-derived filter 206 of the second set of m-derived filters 206 may be symmetrical and the second count ‘K’ and values of components of each second m-derived filter 206 may depend on the optimum loads for different devices along with the associated parasitic effects. The second m-derived filters 206 may be arranged in one of: lumped, quasi-lumped (lumped and transmission lines), and fully transmission line configurations.

The second set of m-derived filters 206 may be configured to implement a phase offset line for creating an open circuit to the current from the main path at the back-off voltage. Additionally, the second set of m-derived filters 206 may nullify the parasitic effect of the auxiliary transistor 114 and the set of parasitic components associated with the auxiliary transistor 114. Upon removing (maybe partially) the parasitic effect via the second set of m-derived filters 206, the auxiliary amplifier may behave as an ideal current source.

The second set of m-derived filters 206 may be configured to combine the functioning of the second output matching network 110B, and the phase offset line 112B of the conventional Doherty power amplifier 100. Further, each second m-derived filter 206 of the second set of m-derived filters 208 includes a series arm inductor 218(1-K) and a shunt arm resonator 220(1-K) to design m-derived low-pass configuration for enabling wideband performance. In other words, the impedance associated with the series arm inductor 218(1-K) may be distributed on both sides of the shunt arm resonator 220(1-K). Further, each of the series arm inductor 218(1-K) and the shunt arm resonator 220(1-K) may be selected based on a predefined phase variation and an image impedance in the predefined frequency range. The impedance of the series inductor 218(1-K) may be denoted by mₚ₁Zₚ₁, mₚ₂Zₚ₂, . . . , m_{pK}Z_{pK} corresponding to each of the second set of m-derived filters 206-1, 206-2, . . . , 206-K respectively. It should be noted that the m-factor mₚ₁, mₚ₂, . . . , m_{pK} represents an order of an individual second m-derived filter 206. It may be noted that the value of the m-factor ranges from 0 to 1. As discussed earlier, the m-factor may be obtained using equation (1). Upon varying the value of the m-factor, the impedance value of each of the series inductors 218(1-K) may span from an open value to a short value. The open value may refer to a very large value or an ideally infinite value and the short value may refer to a very small value or an ideally zero value. Further, the value of the impedance value of each capacitor 222(1-K) of the corresponding shunt arm series resonator 220(1-K) may be in the form of m_{q1}Z_{q1}, m_{q2}Z_{q2}, . . . , m_{qK}Z_{qK} and impedance value of each inductor 224(1-K) of the corresponding shunt arm series resonator 220(1-K) may be in the form of

$${Z}_{p 1} ( 1 - {m}_{p 1}^{2} ) / 4 {m}_{p 1} , … {Z}_{pK} ( 1 - {m}_{pK}^{2} ) / 4 {m}_{pK} ,$$

corresponding to each ‘K’ second m-derived filters 206. The capacitance (C_{q1}, . . . , C_{qK}) of a corresponding capacitor 222(1-K) and inductance (Lₚ₁, . . . , L_{pK}) of a corresponding inductor 224(1-K) for the corresponding characteristic impedance Zₚ₁, . . . , Z_{pK} may be determined as per equations (4) and (5) respectively given below:

$${L}_{p K} = \frac{{Z}_{p K}}{2 π {f}_{c}} \qquad ( 4 )$$

$${C}_{q K} = \frac{1}{2 π {Z}_{q K} {f}_{c}} \qquad ( 5 )$$

The third set of m-derived filters 208 may be coupled to the junction point 116 of the main path and the auxiliary path of the Doherty power amplifier 200. The third set of m-derived filters 208 may be configured to implement a wideband output impedance transformer. The third set of m-derived filters 208 may be configured to ensure that the combined output results in the output impedance of about, but not limited to, 5002 over the predefined frequency range. The third set of m-derived filters 208 may compensate for amplitude and phase variations, ensuring efficient power combination without significant distortion. The third set of m-derived filters 208 utilized the ability of m-derived filters to achieve variable image impedance, enabling frequency-dependent transformation when needed, enhancing the wideband performance of the third set of m-derived filters 208 enabling an m-derived QWT. The third set of m-derived filters 208 may include a third count ‘L’ of third m-derived filters 208(1-L). Each third m-derived filter 208 of the third set of m-derived filters 208 may be symmetrical and may include a series arm inductor 226(1-L) and a shunt arm resonator 228(1-L). Further, the impedance value of each of the series arm inductor 226(1-L) and the impedance value of each of the shunt arm resonator 228(1-L) may be selected based on a predefined phase variation and an image impedance in the predefined frequency range. In an embodiment, a quasi-lumped configuration of the third set of m-derived filters 208 may allow a compact design of the DPA 200 especially at lower frequencies range of about, but not limited to, 5G bands below 1 GHz. The configuration of the third set of m-derived filters 208 may achieve variable image impedance in response to the frequency of the input signal, as per the requirement.

In other words, impedance value of the series arm inductor 226(1-L) may be denoted as mᵤ₁Zᵤ₁, mᵤ₂Zᵤ₂, . . . , m_{uL}Z_{uL} corresponding to each of the first set of m-derived filters 208(1-L) respectively. The impedance value of the series arm inductor 226(1-L) may be distributed on either side of the corresponding series resonator 228(1-L) connected in the shunt arm of each of the third m-derived filter 208, as 226A(1-L) and 226B(1-L) to maintain the symmetry. It should be noted that the m-factor mᵤ₁, mᵤ₂, . . . , m_{uL} represents an order of an individual third m-derived filter 208 in the third set of m-derived filters 208. It should be noted that the order of the m-derived offset line section may be selected for efficient power transfer to the junction point 116 to 50Ω load over the predefined wideband frequency range. The m-factor of each of the third set of m-derived filters 208 may be obtained by using the equation (1). It may be noted that the value of the m-factor may range from 0 to 1. Upon varying the value of the m-factor, the impedance value may span from an open value to a short value. Further, impedance value of each capacitor 230(1-L) of the shunt arm series resonator 232(1-L) may be in the form of mᵥ₁Zᵥ₁, mᵥ₂Zᵥ₂, . . . , m_{vL}Z_{vL} and impedance value of each inductor 232(1-L) of the corresponding shunt arm series resonator 228 may be in the form of

$${Z}_{u 1} ( 1 - {m}_{u 1}^{2} ) / 4 {m}_{u 1} , … {Z}_{uL} ( 1 - {m}_{u L}^{2} ) / 4 {m}_{uL} ,$$

corresponding to each ‘L’ third m-derived filters 208. The capacitance (Cᵥ₁, Cᵥ₂, . . . , C_{vL}) of a corresponding capacitor 230(1-L) and the corresponding characteristic inductance (Lᵤ₁, Lᵤ₂, . . . , L_{uL}) of the inductor 232(1-L) for the corresponding characteristic impedance Zᵤ₁, Zᵤ₂, . . . , Z_{uL} may be determined as per equations (6) and (7) respectively given below:

$${L}_{u L} = \frac{{Z}_{u L}}{2 π {f}_{c}} \qquad ( 6 )$$

$${C}_{v L} = \frac{1}{2 π {Z}_{v L} {f}_{c}} \qquad ( 7 )$$

The higher-order L and C values may also be calculated in the similar manner. Accordingly, the phase or the electrical length of the transmission line may be adjusted by optimizing the higher order L and C values for the respective electrical length by adjusting the cut-off frequency. The capacitance value and the inductance value for both the series inductor 226 and the shunt arm resonator 228, for each of the third set of m-derived filters 208 may be selected such that the third set of m-derived filters 208 may function in a way to depict a higher-order non-linear transmission phase. The order of the third set of m-derived filters 208 may be selected in a way to achieve optimal power transfer from junction point 116 to the output load (for example, 50Ω) over the predefined frequency range.

It may be noted that the first input matching network 106A and the second input matching network 106B may be connected at the input of the main PA and the auxiliary PA respectively for matching input impedances of devices in the main path and the auxiliary path, respectively as shown in FIG. 2. In an embodiment, the first input matching network 106A may be implemented using a fourth set of m-derived filters (not shown) and the second input matching network 106B may be implemented using a fifth set of m-derived filters (not shown) to operate in the predefined wideband frequency range. The fourth set of m-derived filters and the fifth set of m-derived filters may be designed similarly to the first set of m-derived filters 206, the second set of m-derived filters 206 and/or the third set of m-derived filters 208.

Further, the DPA 200 may include the first input offset 104A to compensate for the output offset line in the auxiliary path and the second input offset 104B to provide a 50Ω characteristic impedance line with a 90° phase shift in the auxiliary path to compensate for the phase of the first QWT 204 in the main path. This ensures proper phase alignment between the two branches for the DPA operation. The input phase offset line in the main path and an impedance line with a 90° phase shift at the input of the auxiliary path can also be realized using m-derived filters.

The circuit diagram of the proposed wideband m-derived filter-based DPA architecture 200 as shown in FIG. 2. RF power may be fed at the input of the power divider 102, and output ports of the power divider are each connected to the main path and the auxiliary path.

At low power levels, the auxiliary PA may remain OFF because the auxiliary transistor 114 is biased below the pinch-off voltage or in class-C mode. In contrast, the main transistor 108 of the main PA is biased at or above the pinch-off voltage in class-AB mode, allowing it to operate even at low RF power levels while the auxiliary PA remains inactive. Under these conditions, the main PA is presented with a load impedance higher than its optimal value, leading to voltage saturation even at low output current levels. The first set of m-derived filters 204 enabling the m-derived QWT would provide the load seen by the main transistor 108 with the second set of m-derived filters 206 enabling the m-derived offset line section of the auxiliary path and the third set of m-derived filters 208 enabling the output impedance transformer. Hence, parasitics of the main transistor 108 are absorbed in the m-derived QWT section implemented by the first set of m-derived filters 204, that may also perform the impedance inversion for obtaining required loads to the main transistor 108 from the impedance that appears at junction point 116.

Further, it may be noted that at a specific back-off point, when the output voltage of the main PA reaches its peak value, the auxiliary PA begins to operate and progressively contributes to the output current. This additional current may alter the load presented to the m-derived quarter-wave transformer (QWT), ensuring that the load experienced by the main PA gradually decreases as the input power increases. As a result, the load experienced by the main PA decreases while its output current continues to increase, ensuring that the output voltage of the main PA remains at its peak value from back-off to saturation. Since the main PA operates in voltage saturation (with the output voltage maintained at its peak) even at back-off power levels, it achieves high efficiency. Additionally, the issue of current leakage from the main PA to the auxiliary PA during back-off (when the auxiliary PA is OFF) is effectively eliminated by the second set of m-derived filters 206 implementing the m-derived low-pass offset line section, which provides frequency-agile parasitic compensation for the auxiliary transistor. It may be noted m-derived filters of the first set 204, the second set 206 and the third set 208 may replicate the behaviour of a transmission line with phase and image impedance that varies nonlinearly with frequency. By appropriately selecting the filter elements, the desired variation of phase and image impedance across a frequency band can be achieved.

The first set of m-derived filters 204 may be designed with prior knowledge of the set of parasitic components of both the main transistor 108 and the auxiliary transistor 114. The network parameters of the first set of m-derived filters 204 implementing the wideband m-derived QWT are obtained while considering the main transistor 108, the auxiliary transistor 114, and an impedance Z_{L} presented at the junction point 116 that may be due to the third set of m-derived filters 208 and the second set of m-derived filters 206.

The output side of both main and auxiliary PAs, which includes the first set of m-derived filters 204, the second set of m-derived filters 206, and the third set of m-derived filters 208 may be treated as a simplified three port network, where Z_{L} may be terminating the third port at junction point 116. Here, Z_{L} is the load impedance which appears at the junction point 116 towards the third set of m-derived filters 208 when it is terminated by 50Ω. Thus, the third set of m-derived filters 208 enabling the wideband m-derived output impedance transformer performs a transformation from 50Ω to load Z_{L} at the junction point 116. Since the parasitic network parameters of the main transistor 108 and the auxiliary transistor 114 are known from the transistor data, the network parameters of the first set of m-derived filters 204, the second set of m-derived filters 206, the third set of m-derived filters 208 and the Z_{L}, may be obtained by enforcing the optimum load conditions of Doherty amplifiers' 200 operation at back-off and saturation.

Further, a back-off factor (β) may be associated with the back-off range at which efficiency enhancement is required in the operation of the Doherty power amplifier 200. By way of an example, a 6 dB back-off corresponds to a back-off factor β=0.5, that may result in a load of 2·Rₒₚₜ terminating the main PA at the back-off point. However, with the increase in the input drive, load modulation introduced by the auxiliary transistor 114 may cause a higher effective load to be presented to the main amplifier 108 due to the non-linear current profile of the auxiliary transistor 114. The increase in the effective load may lead to excessive voltage swing, exceeding the maximum voltage rating of the main transistor 108, resulting in voltage clipping and increased non-linearity. Therefore, the network parameters of the first set of m-derived filters 204 may be obtained by considering the effective load presented to the main amplifier 108 that may be less than Rₒₚₜ/β at the back-off point. The network parameters of the wideband QWT 204 and the wideband offset line 206 may be represented as Y, Z, ABCD or S-parameters.

The first set of m-derived filters 204 may be designed with prior knowledge of the set of parasitic components of both, the main transistor 108 and the auxiliary transistor 114. The value of the series arm inductor 210 and the value of the shunt arm resonator 212 may be selected based on a predefined phase variation and an image impedance in the predefined frequency range. In other words, the value of the series arm inductor 210 and the value of the shunt arm resonator 212 may be selected considering the main transistor 108, the auxiliary transistor 114 and the load impedance at the junction point 116 due to the phase offset line 206 and a wideband output impedance transformer 208. Further, a back-off factor (β) may be associated with the back-off range at which efficiency enhancement is required in the operation of the Doherty power amplifier 200. By way of an example, a 6 dB back-off corresponds to the back-off factor β=0.5 that may result in the impedance of 2·Rₒₚₜ terminating the main amplifier at the back-off point. However, with the increase in the input drive, a load modulation introduced by the auxiliary transistor 114 may cause a raise in the effective load to the main amplifier due to the non-linear current profile of the auxiliary transistor 114. The increase in the effective load may lead to excessive voltage swing, exceeding the maximum voltage rating of the main transistor 108, resulting in voltage clipping and increased non-linearity. Therefore, the network parameters of the first set of m-derived filters 204 may be obtained by considering the effective load presented to the main amplifier may be less than Rₒₚₜ/β at the back-off point. The network parameters of the wideband QWT 204 may be represented as Y, Z, ABCD or S-parameters.

In an embodiment, the network parameters may be obtained by considering the load presented to the main amplifier 108 less than Rₒₚₜ/β at the back-off point. Upon obtaining the network parameters of the first set of m-derived filters 204, the circuit topology may be determined. Based on the network parameters, the first set of m-derived filters 204 may be topologically configured in one of: a lumped configuration, a quasi-lumped configuration, or a fully transmission line configuration. Accordingly, the phase or the electrical length of the transmission line may be adjusted by optimizing the higher order L and C values for the respective electrical length on adjusting the cut-off frequency.

The above methodology of obtaining network parameters of the wideband m-derived QWT 204 and the m-derived offset line 206 along with the m-derived output impedance transformer 208 with a prior knowledge of devices parasitics of the main transistor 108 and the auxiliary transistor 114 as described above provides enhancement over the conventional DPA 100. The designing of the matching networks ensures that the optimal load Rₒₚₜ is applied, even as the load at junction point 116 varies dynamically with input drive due to load modulation. Further, leakage of current from the main PA to the auxiliary PA is minimised by the quasi-open circuit condition provided by the wideband m-derived offset line 206 when the auxiliary PA is OFF during low-power operation. This is achieved by carefully designing the wideband m-derived QWT 206 to function effectively in the presence of the quasi-open circuit condition at junction point 116. Further, this configuration of DPA 200 ensures that appropriate loads are applied to the main transistor 108 and the auxiliary transistor 114, preventing voltage clipping and maintaining linearity throughout the operation.

Referring now to FIG. 3A, simulated results 300A depicting drain efficiency of the Doherty power amplifier 200 of FIG. 2 as compared to the conventional Doherty power amplifier 100 at the back-off voltage point is illustrated in accordance with an embodiment of the present disclosure. In other words, the line graph 300A may include a line 302A corresponding to the simulation result of the conventional Doherty power amplifier 100 and a line 304A corresponding to the m-derived Doherty power amplifier 200 at the back-off voltage point. The line graph 300A depicts the drain efficiency with respect to a frequency range starting from 1.2 GHz to 2.8 GHz in steps of 0.2 GHz. Table 1 below provides a comparison of fractional bandwidths of conventions DPA 100 and the m-derived DPA 200 at 60% DE range and at 6 dB back-off power range.

TABLE 1

| Doherty Power Amplifier | Frequency (GHz) | Fractional BW |
|---|---|---|
| Conventional | 1.72-2.22 GHz = 0.498 GHz | 25.27% |
| m-derived | 1.52-2.63 GHz = 1.11 GHz | 53.49% |

The line graph 300A and the Table 1 depicts that the m-derived Doherty power amplifier 200 significantly extends the bandwidth in the back-off condition, achieving more than double the bandwidth of the conventional Doherty power amplifier 100. The Fractional bandwidth is increased from 25.27% to 53.49%, demonstrating a significant improvement in wideband performance.

Referring now to FIG. 3B, simulated results 300B depicting drain efficiency of the Doherty power amplifier 200 of FIG. 2 as compared to the conventional Doherty power amplifier at saturation point is illustrated, in accordance with an embodiment of the present disclosure. In other words, the line graph 300B depicts a line 302B corresponding to the simulation result of the conventional Doherty power amplifier 100 and a line 304B corresponding to the m-derived Doherty power amplifier 200 at the saturation voltage point. The line graph 300B depicts the drain efficiency with respect to a frequency range starting from 1.2 GHz to 2.8 GHz in steps of 0.2 GHz. Table 2 below provides a comparison of fractional bandwidths of the conventions DPA 100 and the m-derived DPA 200 at 60% DE range and at saturation point.

TABLE 2

| Doherty Power | | |
|---|---|---|
| Amplifier | Frequency (GHz) | Fractional BW |
| Conventional | 1.511-2.479 GHz = 0.968 GHz | 48.52% |
| m-derived | 1.22-2.80 GHz = 1.58 GHz | 78.61% |

Table 2 and the line graph 300B depicts that the m-derived Doherty power amplifier 200 provides a 63% increase in bandwidth as compared to the conventional Doherty power amplifier 100 in a frequency range starting from 0.968 GHz to 1.58 GHz. The fractional bandwidth of the m-derived Doherty power amplifier 200 increases from 48.52% to 78.61% indicating an improvement in performance for wideband applications.

Thus, the disclosed system tries to overcome the narrow bandwidth problem of the conventional Doherty power amplifier. The transformer ratio required by the QWT may vary with frequency due to the dependence of the set of parasitic elements on frequency. The capability of m-derived filters to realize the variable image impedance may provide the required variable transformation ratio over the operational frequency band. Additionally, the variable transformation ratio provides the wide bandwidth capability to the m-derived QWT. Further, high performance may be maintained at the back-off power levels.

As will be appreciated by those skilled in the art, the system described in the various embodiments discussed above are not routine, or conventional, or well-understood in the art. The system discussed above provide for wideband Doherty power amplifier 200.

In light of the above-mentioned advantages and the technical advancements provided by the disclosed system, the claimed steps as discussed above are not routine, conventional, or well understood in the art, as the claimed steps enable the following solutions to the existing problems in conventional technologies. Further, the claimed steps bring an improvement in the functioning of the device itself as the claimed steps provide a structural solution to the problem.

The specification has described the wideband Doherty power amplifier. The illustrated designs are set out to explain the exemplary embodiments shown, and it should be anticipated that ongoing technological development will change the manner in which particular designing are performed. These examples are presented herein for the purpose of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A,B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A Doherty power amplifier comprising:
a first set of m-derived filters coupled to an output of a main transistor of a main path of the Doherty power amplifier;
a second set of m-derived filters coupled to an output of an auxiliary transistor of an auxiliary path of the Doherty power amplifier; and
a third set of m-derived filters coupled to a junction point of the main path and the auxiliary path,
wherein the Doherty power amplifier is configured to operate at a predefined back-off power range in a predefined frequency range.

2. The Doherty power amplifier of claim 1, wherein:
the first set of m-derived filters is configured to implement a wideband quarter wave transformer (QWT),
the second set of m-derived filters is configured to implement a phase offset line; and
the third set of m-derived filters is configured to implement a wideband output impedance transformer.

3. The Doherty power amplifier of claim 1, wherein:
the first set of m-derived filters comprises a first count (N) of m-derived filters,
the second set of m-derived filters comprises a second count (K) of m-derived filters, and
the third set of m-derived filters comprises a third count (L) of m-derived filters, and
wherein each of the first count (N), the second count (K), and the third count (L) is determined based on an operating frequency in the predefined frequency range.

4. The Doherty power amplifier of claim 3, wherein each m-derived filter of each of: the first set of m-derived filters, the second set of m-derived filters, and the third set of m-derived filters are symmetrical.

5. The Doherty power amplifier of claim 4, wherein each m-derived filter comprises a series arm inductor and a shunt arm resonator.

6. The Doherty power amplifier of claim 5, wherein each of the series arm inductor and the shunt arm resonator is selected based on a predefined phase variation and an image impedance in the predefined frequency range.

7. The Doherty power amplifier of claim 1, wherein:
the first set of m-derived filters are coupled to a drain of the main transistor and the junction point, and
the second set of m-derived filters are coupled to a drain of the auxiliary transistor and the junction point.

8. The Doherty power amplifier of claim 1, wherein each of the first set of m-derived filters, the second set of m-derived filters, and the third set of m-derived filters are topologically configured in one of:
a lumped configuration;
a quasi-lumped configuration; or
a fully transmission line configuration.

9. The Doherty power amplifier of claim 1, further comprising:
a fourth set of m-derived filters coupled to an input of the main transistor of the main path; and
a fifth set of m-derived filters coupled to an input of the auxiliary transistor of the auxiliary path,
each of the fourth set of m-derived filters and the fifth set of m-derived filters having a predefined characteristic impedance value.

10. A wideband Doherty power amplifier, comprising:
a first set of m-derived filters coupled to an output of a main transistor of a main path of the wideband Doherty power amplifier;
a second set of m-derived filters coupled to an output of an auxiliary transistor of an auxiliary path of the wideband Doherty power amplifier; and
a third set of m-derived filters coupled to a junction point of the main path and the auxiliary path,
wherein the wideband Doherty power amplifier is configured to operate at a predefined back-off power range in a predefined frequency range covering a predefined wide bandwidth.
